(19) United States
(12) Patent Application Publication
(10) Pub. No.: US 2014/0273825 A1
(43) Pub. Date: Sep. 18, 2014

(54) Semiconductor Chip Configuration with a Coupler

(71) Applicant: INFINEON TECHNOLOGIES AG, Neubiberg (DE)

(72) Inventors: Giuseppina Sapone, Villach (AT); Saverio Trotta, Muenchen (DE)

(73) Assignee: INFINEON TECHNOLOGIES AG, Neubiberg (DE)

(21) Appl. No.: 13/838,980

(22) Filed: Mar. 15, 2013

(51) Int. Cl. H01L 23/60

(52) U.S. Cl. CPC H01L 23/60
USPC 455/41.1; 257/664; 438/26

(57) ABSTRACT

A semiconductor device comprises a semiconductor substrate, a primary coil, and a secondary coil. The primary coil of a coupler is disposed over the semiconductor substrate and the secondary coil of the coupler is disposed over the semiconductor substrate adjacent to the primary coil. The primary coil includes a first end coupled to a first contact terminal, a second end coupled to a second contact terminal, and a first center tap coupled to a reference node.

### TECHNICAL FIELD

The present invention relates generally to semiconductor packages, and more particularly to a semiconductor chip configuration with a coupler.

### BACKGROUND

Recently, interest in the millimeter wave spectrum at 30 GHz to 300 GHz has drastically increased. The emergence of low cost, high performance Si-based technologies has opened a new perspective for system designers and service providers seeking to manufacture semiconductor devices that function within the millimeter wave spectrum. These Si-based technologies enable the development of millimeter wave radio devices at the same cost structure of radios operating in the gigahertz range or less.

In combination with available ultra-wide bandwidths, this makes the millimeter wave spectrum more attractive than ever before for supporting a new class of systems and applications. For instance, millimeter wave devices may be used for applications ranging from ultra-high speed data transmission, video distribution, portable radar, sensing, detection, and imaging of all kinds.

However, taking advantage of the millimeter wave radio spectrum involves the ability to design and manufacture low cost, high performance radio frequency front end circuits for millimeter wave semiconductor devices. In some cases, designing and manufacturing front end circuits for millimeter wave semiconductor devices may be more complex than desired. Additional components may be needed to provide protection from mechanical and environmental risks while still maintaining optimum signal performance of devices designed to function at millimeter wave frequencies.

### SUMMARY OF THE INVENTION

In accordance with an embodiment of the present invention, a semiconductor device comprises a semiconductor substrate, a primary coil, and a secondary coil. The primary coil of a coupler is disposed over the semiconductor substrate and the secondary coil of the coupler is disposed over the semiconductor substrate adjacent to the primary coil. The primary coil comprises a first end coupled to a first contact terminal, a second end coupled to a second contact terminal, and a first center tap coupled to a reference node.

In accordance with an alternative embodiment of the present invention, a semiconductor package comprises a primary coil and a secondary coil of a coupler. The primary coil is disposed within a semiconductor chip and the secondary coil is disposed within an insulating material outside the semiconductor chip. The secondary coil comprises a center tap connection coupled to a reference node.

In accordance with an alternative embodiment a method of forming a semiconductor package includes providing a semiconductor substrate, forming a secondary coil in a first metal layer over the semiconductor substrate, forming a first dielectric layer over the secondary coil, forming a primary coil in a second metal layer over the first dielectric layer and the secondary coil, forming a connection between a first center tap of the primary coil and a reference node, and forming contact terminals coupled to the primary coil.

In accordance with yet another embodiment of the present invention, a method for operating a semiconductor device is presented. A semiconductor device comprises a semiconductor substrate and a coupler including a primary coil and a secondary coil. The primary coil is disposed over the semiconductor substrate and a secondary coil is disposed over the semiconductor substrate adjacent to the primary coil. The primary coil comprises a first end coupled to a first contact terminal, a second end coupled to a second contact terminal, and a first center tap coupled to a reference node. A millimeter wave signal is applied to the first and second contact terminals. The millimeter wave signal is received from the primary coil via the secondary coil. The receiving is performed by a circuit disposed on the semiconductor substrate that is coupled to the secondary coil.

### BRIEF DESCRIPTION OF THE DRAWINGS

For a more complete understanding of the present invention, and the advantages thereof, reference is now made to the following descriptions taken in conjunction with the accompanying drawing, in which:

FIG. 1 illustrates a schematic of a semiconductor package;

FIGS. 2A and 2B illustrate a schematic of a semiconductor package with a millimeter wave signal source;

FIG. 3 illustrates a schematic of a semiconductor package coupled to a load;

FIG. 4 illustrates a top view of a coupler;

FIG. 5 illustrates a perspective view of a coupler;

FIG. 6 illustrates a cross-sectional view of a semiconductor package;

FIG. 7 illustrates a schematic of an alternative embodiment of a semiconductor package;

FIG. 8 illustrates a cross-sectional view of an alternative embodiment of a semiconductor package;

FIG. 9 illustrates a perspective view of an alternative configuration of a coil in a coupler;

FIG. 10 illustrates a flowchart of a process for forming a semiconductor package with electrostatic discharge protection;

FIG. 11 illustrates a flowchart of a process for operating a semiconductor device; and

FIGS. 12A and 12B illustrate a circuit schematic of a semiconductor package.

Corresponding numerals and symbols in the different figures generally refer to corresponding parts unless otherwise indicated. The figures are drawn to clearly illustrate the relevant aspects of the embodiments and are not necessarily drawn to scale.

### DETAILED DESCRIPTION OF ILLUSTRATIVE EMBODIMENTS

The making and using of various embodiments are discussed in detail below. It should be appreciated, however, that the present invention provides many applicable inventive concepts that can be embodied in a wide variety of specific contexts. The specific embodiments discussed are merely illustrative of specific ways to make and use the invention, and do not limit the scope of the invention.

Many applications based on wireless transmission at millimeter wave frequencies may need a package structure that protects the components within the package from mechanical and environmental stress. For example, electrostatic discharge (ESD) events (e.g., pulses) may damage or destroy gate oxide, metallization, junctions, and other components within the semiconductor package. ESD events may be caused by a variety of sources such as a charged body touching an integrated circuit, a charged integrated circuit touching a grounded surface, a charged machine touching an integrated circuit, and various other sources.

To combat potential damage from ESD events, currently used semiconductor packages may include large clamping devices that limit the voltage swing of the signal at the contact terminals. In high-speed and radio-frequency (RF) applications, however, the parasitic capacitance of ESD protection circuits may degrade the high-frequency signal. Moreover, the addition of ESD protection devices increases the cost and complexity of the system.

The currently used methods for ESD protection work differently at different frequencies. For instance, ESD protection devices for low frequency devices may provide signal losses that may be acceptable. However, at high frequencies such as millimeter wave frequencies, the signal loss implicated by such devices may degrade the performance of the circuit.

In an embodiment, a millimeter wave semiconductor device includes a coupler in which the primary coil has a center tap coupled to a low impedance node, such as a ground node. In some embodiments, the center tap is a common-mode section of the coil to which contact may be made. The low impedance node at the center tap provides a common-mode/low impedance path for ESD pulses at low frequencies, while allowing for no signal attenuation at high frequencies when a purely differential signal is applied between the two ends of the primary coil.

A schematic layout of the semiconductor package will be described using FIG. 1. Alternative layouts will be described using FIGS. 2, 3, 4, 7, and 12. Structural embodiments of the semiconductor package will be described using FIGS. 4-6, 8, and 9. Methods of forming and operating the semiconductor package will be described using FIGS. 10 and 11.

Referring to FIG. 1, a semiconductor package 10 includes a semiconductor chip 12, which comprises a front end circuit 14 for a transmitter or a receiver. In these examples, the front end circuit 14 is coupled to an antenna 16 through a coupler 18. The front end circuit 14 may be configured to operate at a millimeter wave frequency of between about 30 GHz to about 300 GHz, but also may be configured to operate at lower or higher frequencies as well.

In this depicted example, the coupler 18 includes a primary coil 20 and a secondary coil 22, which are both part of the semiconductor chip 12. The antenna 16 may be part of the semiconductor package 10 or may be a separate unit coupled to the semiconductor package 10 through a printed circuit board. It should be understood that primary coil 20 and secondary coil 22 of coupler 18 may be magnetically coupled and/or electrostatically coupled for all of the embodiments described herein. Furthermore, in some embodiments, coupler 18 may function as a transformer in which primary coil 20 is magnetically coupled to secondary coil 22.

The semiconductor package 10 has an input/output coupled to the antenna 16. As will be described in more detail, embodiments of the invention may be applied to a variety of receiver and transmitter chip-in-package millimeter wave designs.

In various embodiments, the front end circuit 14 may include circuit 28 coupled to the secondary coil 22 of the coupler 18. The circuit 28 may include, for example, a receiver circuit, a transmitter circuit, a transceiver circuit, or other circuit type. In the depicted embodiment, the circuit 28 is a transmitter implemented using a MOSFET differential amplifier. The MOSFET differential pair includes a first transistor M1 and a corresponding second transistor M2 coupled to a common source node. The MOSFET differential pair has a first input voltage node Vᵢₙ₁ and a second input voltage node Vᵢₙ₂ thereby forming a differential input, and a first output voltage node Vₒᵤₜ₁ and a second output voltage node Vₒᵤₜ₂ thereby forming a differential output. As a consequence, the maximum and minimum voltage levels are well defined and independent of the input common mode voltage. In various embodiments, the device parameters for the first transistor M1 and the second transistor M2 are the same. The transistors are biased using a common current source 29, and to a supply voltage VDD through the resistors.

Of course, other configurations of components may be present in the front end circuit 14. For example, the front end circuit 14 may include additional circuitry, such as a receiver circuit, frequency generation circuits, baseband circuits, and other suitable components. In some embodiments, the front end circuit 14 may include a frequency conversion circuit that may convert signals to and from baseband.

The primary coil 20 comprises a first end and a second end. The first end is coupled to a first contact terminal 21 while the second end is coupled to a second contact terminal 23. The first contact terminal 21 and the second contact terminal 23 may be configured such that these contact terminals are protected from ESD by a first center tap 24 coupled to a reference node. In particular, the first contact terminal 21 and the second contact terminal 23 are configured to receive an ESD pulse and shunt the ESD pulse to an ESD path coupled to the reference node via the first center tap 24. The reference node is configured to be coupled to ground in these examples. In other words, the reference node may be a ground node. As a result, energy from an ESD event will be shunted to ground instead of passing through the device and damaging components within the semiconductor chip 12 and the front end circuit 14. Alternatively, the reference node may be coupled to another ESD supply node, such as a power supply or a dedicated ESD ground node.

In other embodiments, the reference node may be coupled to a reference plane (not shown) or other component, depending on the particular implementation. In some embodiments, an inductance of the primary coil 20 and a capacitance of the first contact terminal 21 and the second contact terminal 23 may form a parallel resonance at a frequency within a passband of the front end circuit 14. This parallel resonance may reduce the effect of the parasitic capacitance of the first and second contact terminals 21 and 23.

The secondary coil 22 also includes a first end coupled to the front end circuit 14. The secondary coil 22 may optionally include a second center tap 26 that may be coupled to a reference node in some illustrative embodiments. The second center tap 26 may provide additional protection of semiconductor chip 12 from damage due to ESD. Both the first center tap 24 and the second center tap 26 may have a low impedance path to an external ground terminal 30. In these examples, the external ground terminal 30 may be connected to ground but in other illustrative examples, the external ground terminal 30 may be coupled to another potential.

In some embodiments, the second center tap 26 may be coupled to a biasing circuit. Thus, the second center tap 26 may provide bias to the front end circuit 14. The bias may be transparent to the front end circuit 14 at high frequencies, when a purely differential signal connection is implemented between the two ends of the secondary coil 22, because of the common-mode path provided by the second center tap 26 connection to the biasing circuit. In other implementations of an illustrative embodiment, the second center tap 26 may be omitted, depending on the desired functionality of the semiconductor chip 12.

With this configuration of an illustrative embodiment, potential damage from an ESD event may be reduced. In particular, the semiconductor package 10 shown in FIG. 1 provides a low inductance to ground. Additionally, the semiconductor package 10 may provide a single-ended signal interface when the signal received from the antenna 16 is fed only to one contact terminal. Moreover, this configuration of the semiconductor package 10 is highly efficient both for ESD protection and for signal performance over multiple frequencies.

FIG. 2, which includes FIGS. 2A and 2B, illustrates a schematic of the semiconductor package 10 with a millimeter wave signal source. FIG. 2A illustrates a millimeter wave transmitter/receiver, while FIG. 2B illustrates a millimeter wave signal source coupled to the semiconductor package 10.

Referring to FIG. 2A, a millimeter wave signal source 32 transmits signals through an antenna 34 to the antenna 16 associated with the semiconductor package 10. Accordingly, the millimeter wave signal source in this example is a wireless communications source. These signals transmitted by the millimeter wave signal source 32 may be processed by the front end circuit 14, converted to baseband, and passed to another location.

In this example, the second center tap 26 is coupled to a bias generator 27. The bias generator 27 may be located within the front end circuit 14. Of course, in other embodiments, the bias generator 27 may be located elsewhere within the semiconductor chip 12, depending on the functionality involved.

In alternative implementations of an illustrative embodiment, a receiver 33 may receive millimeter wave signals sent by the antenna 16 via an antenna 35 associated with the receiver 33. In this instance, the front end circuit 14 may convert signals from baseband to be transmitted via the antenna 16.

In FIG. 2B, the millimeter wave signal source 32 is physically connected to the first contact terminal 21 and the second contact terminal 23. This configuration of the semiconductor package 10 also provides protection from potential damage due to ESD.

FIG. 3 illustrates the semiconductor package 10 coupled to a load 38. In this instance, the first contact terminal 21 and the second contact terminal 23 are output terminals coupled to the load 38.

Turning next to FIG. 4, a top view of the coupler 18 is depicted. The primary coil 20 is oriented directly above the secondary coil 22. A portion of the secondary coil 22 is also transparent to display features of the second center tap 26 from above.

In this embodiment, the semiconductor chip 12 includes a reference plane 40. The reference plane 40 surrounds the primary coil 20 and the secondary coil 22. The reference plane may be disposed in a metal layer below the primary coil 20 and the secondary coil 22. The reference plane 40 is coupled to a reference node in these examples. Particularly, the reference plane 40 is coupled to the reference node that is coupled to the first center tap 24 of the primary coil 20.

When an ESD event occurs, current will flow through this path and dissipate in the reference plane 40 such that no damage occurs to the components within semiconductor package 10. The reference plane 40 is a ground plane in this embodiment. In other examples, the reference plane 40 may be another type of plane.

As illustrated, the first end and second end of the primary coil 20 are oriented toward the first contact terminal 21 and the second contact terminal 23 (not shown). Likewise, the first and second end of the secondary coil 22 are oriented toward the front end circuit 14 as shown in more detail in FIG. 1.

The coupler 18 may also include a bias connection 42. The bias connection 42 may be coupled to the secondary coil 22 through the second center tap 26 to provide a bias voltage to the second center tap 26. In some embodiments, the bias connection 42 may be coupled to ground or to a low impedance signal path to provide further protection against damage from ESD. The second center tap 26 is coupled to the bias connection 42 through a via in this example.

FIG. 5 illustrates a perspective view of the coupler 18 in the semiconductor package 10. As shown, the various components of the coupler 18 and the underlying semiconductor circuit are implemented using various layers 50.

In FIG. 6, a cross-sectional view of the semiconductor package 10 is shown taken along the lines 6-6 in FIG. 4. The semiconductor chip 12 comprises a substrate 62, which may include active devices formed within.

In this embodiment, the layers 50 of the semiconductor chip 12 may be seen more clearly. The layers 50 may be comprised of a number of different types of material. For example, one layer in the layers 50 may be a p-well that provides a different doping than the substrate. Other example materials for the layers 50 include dielectric materials such as silicon Dioxide and silicon Nitride, p-well, epitaxial layers, metallization layers, polysilicon.

In some embodiments, a p-well may be disposed over the substrate 62. In this illustrative embodiment, however, the p-well is absent.

A metallization layer stack 64 is disposed over the substrate 62. Metallization layer stack 64 may comprise a number of metal levels in various embodiments, for example, the metallization layer stack 64 may comprise ten or more metal levels in one embodiment. In this particular example, the metallization layer stack 64 may comprise four metal levels. These metal layers may include copper or other suitable metals.

In the illustrated embodiment of FIG. 6, the bias connection 42 is disposed in the lowermost layer (M1) of the metallization layer stack 64. Metallization layer stack 64 may comprise a number of metal levels and inter-metallization dielectrics in various embodiments. For example, the metallization layer stack 64 may comprise ten or more metal levels and inter-metallization dielectrics in one embodiment. In this particular example, the metallization layer stack 64 may include four metal levels and inter-metallization dielectrics. However, in alternative embodiments, other number of metal layers and inter-metallization dielectrics may be used depending on the particular process used. The reference plane 40 is coupled to second center tap 26 of secondary coil 22 are disposed over the next layer (M2) of the metallization layer stack 64. The secondary coil 22 is disposed in a layer (M3) above the second center tap 26, and the secondary coil is coupled to the second center tap 26 and the front end circuit 14.

As depicted, first center tap 24 of primary coil 20 is disposed above the secondary coil 22. The first center tap 24 is coupled to the reference node (not shown) which is then coupled to the reference plane 40. The primary coil 20 is then disposed over the semiconductor chip 12 in the uppermost layer (M4) of the metallization layer stack 64 and coupled to the first contact terminal 21 and the second contact terminal 23 of the semiconductor package 10. In an embodiment, the first center tap 24 is implemented using a via between layer (M4) and layer (M2), and the second center tap 26 is implemented using a via between layer (M3) and layer (M1). It should be understood that the implementation of first center tap 24 and second center tap 26 shown in FIG. 6 is just one of many example embodiments. In alternative embodiments, first center tap 24 and second center tap 26, as well as the other layers used to implement primary coil 20 and secondary coil 22, may be implemented differently.

A passivation layer 68 is located above the metallization layer stack 64. This passivation layer 68 is disposed over the metallization layer stack 64 after forming the components within the metallization layer stack 64. The passivation layer 68 is configured to protect the underlying metallization layer stack 64 and may comprise an oxide such as silicon oxide. In alternative embodiments, the passivation layer 68 may comprise a nitride material. In still other embodiments, the passivation layer 68 may comprise other dielectric materials such as high-k or even low-k materials.

The orientation of the different components within the metallization layer stack 64 shown in this figure is not meant to limit the manner in which the semiconductor chip 12 is formed. In alternative implementations of an illustrative embodiment, the metal layers within the metallization layer stack 64 may be disposed in a different order than described herein. Additional layers may also be present between the different components disposed within the semiconductor chip 12. For example, more than one metal layer may be present between the primary coil 20 and the secondary coil 22. Further, the primary coil 20 may not be disposed in the uppermost metal layer in the metallization layer stack 64. For instance, several metal layers may be present between the passivation layer 68 and the primary coil 20, depending on the particular implementation.

In still other illustrative embodiments, the primary coil 20 and/or the secondary coil 22 may be formed over a plurality of metal levels. For example, in one embodiment, the primary coil 20 may have a first metal level coil, a second metal level coil, a third metal level coil, and a fourth metal level coil. The secondary coil 22 may have a first metal level coil and a second metal level coil. Each of the metal level coils may be interconnected through vias. In alternative implementations, the primary coil 20 may be a single-level coil, while the secondary coil 22 has more than one metal level, or vice versa. Thus, a multi-layer coil may be formed in embodiments of the present invention.

In FIG. 7, an alternative embodiment of the semiconductor package 10 is shown. A first coil of the coupler 18 is disposed within the semiconductor chip 12 and a second coil of the coupler 18 is disposed within an insulating material outside the semiconductor chip 12.

In this example, the secondary coil 22 is located within the semiconductor chip 12, while the primary coil 20 is located in a redistribution layer. A first circuit is also disposed in the redistribution layer of the semiconductor chip 12 and subsequently coupled to the secondary coil 22. This circuit may be an example of the front end circuit 14 shown in FIG. 1 and may be configured to operate at millimeter wave frequencies.

The primary coil 20 is disposed within a second metal layer in the semiconductor package 10. Accordingly, the coupler 18 is comprised of one coil within the semiconductor chip 12 and one coil outside the semiconductor chip 12. The first center tap 24 is also located outside the semiconductor chip 12 in this example.

FIG. 8 illustrates a cross-sectional view of the semiconductor package 10 shown in FIG. 7. The semiconductor package 10 may be formed using methods described in U.S. patent application Ser. No. 13/612,547, entitled “Chip To Package Interface,” filed on Sep. 12, 2012, which is incorporated herein by reference in its entirety.

As illustrated, the secondary coil 22 is located at an uppermost layer (M3) within the semiconductor chip 12. In this particular example, the metallization layer stack 64 may include three metal layers. The secondary coil 22 may be disposed at a top surface and coupled to the front end circuit 14.

An insulating material is located above the passivation layer 68 in this example. In particular, a first dielectric layer 80 may be disposed over the passivation layer 68 and the semiconductor chip 12. The first dielectric layer 80 may be deposited or coated. The first dielectric layer 80 may comprise an oxide layer or an oxide/nitride layer stack. In other examples, the first dielectric layer 80 may comprise silicon nitride, silicon oxynitride, FTEOS, SiCOH, polyimide, photoimide, BCB or other organic polymers, or combinations thereof. An optional insulating liner may be formed above the first dielectric layer 80 comprising a nitride layer, or some other suitable material.

A second dielectric layer 82 is located above the first dielectric layer 80. The second dielectric layer 82 is disposed over the first dielectric layer 80. A third dielectric layer 84 is located above the second dielectric layer 82. The third dielectric layer 84 is disposed over the second dielectric layer 82. The first, the second, and the third dielectric layers 80, 82, and 84 may comprise a same or different material in different embodiments.

The primary coil 20 is shown within a redistribution layer 85 in the second dielectric layer 82. In this example, the primary coil 20 is disposed within the second dielectric layer 82, above the secondary coil 22. Thus, the primary coil 20 is separated from the secondary coil 22 by the first dielectric layer 80 and the passivation layer 68. Advantageously, in various embodiments of the invention, the signal coupling between the primary coil 20 and the secondary coil 22 is performed by means of the interposed dielectric that is formed partly during the fabrication of the semiconductor chip 12 (passivation layer 68) and partly during the fabrication of the semiconductor package 10 (first dielectric layer 80). Therefore, in various embodiments, the separation between the primary coil 20 and the secondary coil 22 may be controlled either during the semiconductor chip fabrication process or subsequently during the package processing. As a result, the signal coupling may be controlled tightly in various embodiments of the present invention, while maintaining a desired level of ESD protection.

The first center tap 24 of primary coil 20 may be routed toward the outer surface of the semiconductor package 10. In some embodiments, the first center tap 24 may be implemented using a via. Accordingly, the primary coil 20 may be connected to the outer surface of the semiconductor package 10 by via 81. The semiconductor package 10 is then soldered to another component (e.g. a printed circuit board) via a solder ball 83.

A portion of the first center tap may be disposed in both the second dielectric layer 82 and a metal layer within the metallization layer stack 64 in the semiconductor chip 12. Thus, the entire primary coil 20 may be disposed above the semiconductor chip 12 while a portion of the first center tap 24 is still part of the metallization layer stack 64 and is coupled to a reference node that is coupled to the reference plane 40. As discussed above, however, the configuration of layers shown in this figure is not meant to limit the manner in which an illustrative embodiment may be implemented.

For example, in alternative embodiments, the primary coil 20 may also be formed in multiple metal levels over the first dielectric layer 80. In one embodiment, the primary coil 20 has a first redistribution level coil and a second redistribution level coil coupled through a redistribution level via. The embodiments of FIG. 8 may be combined with embodiments in which the secondary coil is formed in multiple metal layers of the metallization layer stack 64 thereby forming multi-layer and multi-turn coils in one or more embodiments. Further, other components shown in FIG. 8 may be optional.

With the embodiment shown in this example, both the primary coil 20 and the secondary coil 22 are far removed away from the substrate 62 in contrast to on-chip coupler coils. Accordingly, signal losses toward the substrate 62 are reduced. The absence of physical contact by metallization layers between the semiconductor package 10 and the semiconductor chip 12 at the millimeter wave front-end interface may enhance the robustness of the millimeter wave interface of the packaged device against mechanical and/or environmental stresses and aging. Also, the electromagnetic coupling at the chip-package interface automatically implements an ESD protection device.

FIG. 9 illustrates a perspective view of an embodiment of the coupler 18. While the coupler 18 in FIGS. 3 and 4 is shown in one configuration, other configurations for the coils in coupler 18 may be realized. For example, in various embodiments, the semiconductor package 10 may include coupler coils having different configurations such as multiple coils or multiple turn or multiple loop coils.

As illustrated, the primary coil 20 and the secondary coil 22 are configured with multiple loops. In this embodiment, the primary coil 20 and the secondary coil 22 comprise rectangular coils. The secondary coil 22 may have an underpass 90 within the metallization layer stack 64. Through the underpass 90, the secondary coil 22 may be coupled to input/output nodes of the front end circuit 14 within the semiconductor chip 12. The primary coil 20 may have an overpass 92 that may be coupled to the first and second contact terminals 21 and 23 of the semiconductor package 10. Of course, in other examples, the coupler 18 may comprise coils with other shapes instead of the rectangular coils shown in this Figure.

FIG. 10 describes a process 100 for forming the semiconductor package 10 in accordance with an illustrative embodiment. The process 100 may be used to form the semiconductor package 10 as shown in FIG. 9.

The process begins by forming a semiconductor substrate (step 102). A secondary coil is formed in a first metal layer over the semiconductor substrate (step 104). Next, a first dielectric layer is formed over the secondary coil (step 106). A primary coil is formed in a second metal layer over the first dielectric layer and the secondary coil (step 108). A connection is formed between a first center tap of the primary coil and a reference node (step 110). Forming this connection may include coupling the first center tap 24 of the primary coil 20 to the reference node in which the reference node is a ground node, as described in FIG. 1.

Next, contact terminals are formed and coupled to the primary coil (step 112). A reference plane is formed in a third metal layer bordering the primary coil and the secondary coil (step 114). The reference plane surrounds the primary and secondary coils as shown in FIG. 5. For example, the reference plane 40 may be disposed in a third metal layer beneath both the primary coil 20 and the secondary coil 22. The reference plane is then coupled to the first center tap (step 116) and to a ground node (step 118).

A circuit is formed in the semiconductor substrate (step 120). The front end circuit 14 in FIG. 1 may be one implementation for the circuit formed in step 120. In other illustrative examples, other types of circuits with other features may be formed during this step. An interface of the circuit is then coupled to the secondary coil (step 122). A biasing circuit is formed in the semiconductor substrate (step 124) and the biasing circuit is coupled to a second center tap of the secondary coil (step 126). Finally, the semiconductor package is encapsulated (step 128), with the process terminating thereafter.

FIG. 11 illustrates a process 200 for operating the semiconductor chip 12 in the semiconductor package 10. In particular, process 200 describes operation of the semiconductor package 10 at millimeter wave frequencies to protect the semiconductor package 10 from damage from ESD events. The process 200 may be used with the semiconductor package 10 formed by the process 100, or a semiconductor package formed using some other process, depending on the implementation.

The process begins by applying a millimeter wave signal to first and second contact terminals in the semiconductor device (step 202). The millimeter wave signal may be supplied using the millimeter wave signal source 32 shown in FIGS. 2A and 2B, or some other suitable type of millimeter wave signal source. The millimeter wave signal may be applied at a first frequency.

The millimeter wave signal is then received from the primary coil via the secondary coil (step 204). The receiving step may be performed by a circuit disposed on the semiconductor substrate that is coupled to the secondary coil. For example, the front end circuit 14 may receive the millimeter wave signal via the secondary coil 22.

Next, a bias voltage is applied to a second center tap of the secondary coil (step 206). An ESD pulse is received at the first and second contact terminals (step 208). This ESD pulse is shunted to an ESD signal path coupled to a reference node via the first center tap (step 210). This reference node may be a ground node or may be coupled to a ground plane. Further, the ESD signal path may comprise a metal region surrounding the coupler, such as reference plane 40 shown in FIGS. 4 and 5.

In some cases, a millimeter wave signal may be transmitted to a load coupled to the first and second contact terminals from a circuit coupled to the secondary coil (step 212). Finally, a capacitance of the first and second contact terminals is resonated with an inductance of the primary coil (step 214).

The processes described in FIGS. 10 and 11 are not meant to limit the order in which these steps may be performed. For instance, some steps in process 100 in FIG. 10 may be omitted. As an example, a biasing circuit may not be formed in step 124 or coupled to the second center tap of the secondary coil in step 126 because the functionality of the semiconductor package does not require a second center tap or a biasing circuit. In still other examples, the steps described in FIGS. 10 and 11 may occur substantially concurrently or out of the order described in the figures.

FIG. 12, which includes FIGS. 12A and 12B, illustrates a circuit schematic of a semiconductor package in accordance with an alternative embodiment of the present invention.

In this embodiment, the primary coil 20 is also a differential coil. For example, both the ends of the primary coil 20 may be coupled to an antenna component 300 coupled to the antenna 16. For example, in one case illustrated in FIG. 16A, the conversion from differential signal to single ended signal may be performed within an antenna component 300, which may be part of the printed circuit board or may be a standalone unit. As discussed in prior embodiments, the primary coil 20 is outside the semiconductor chip 12 while the secondary coil 22 is within the semiconductor chip 12.

In another embodiment illustrated in FIG. 12B, the primary coil 20 may be connected directly or by a coupling component 302 to a differential antenna 304, which may be part of the printed circuit board or may be a stand-alone device in various embodiments.

Embodiments of the present invention include a semiconductor device comprising a semiconductor substrate, a primary coil of a coupler, and a secondary coil of the coupler. The primary coil is disposed over the semiconductor substrate. The primary coil comprises a first end coupled to a first contact terminal, a second end coupled to a second contact terminal, and a first center tap coupled to a reference node. The secondary coil is disposed over the semiconductor substrate adjacent to the primary coil. In some embodiments, the primary coil is magnetically and/or electrostatically coupled to the secondary coil. Furthermore, in some embodiments, the coupler may be a transformer.

In the illustrative embodiments, the primary coil is disposed above the secondary coil. Particularly, the primary coil is disposed on a first layer of metal and the secondary coil is disposed on a second layer of metal. The first and second contact terminals are configured to be couple to signal path coupled to the reference node via the first center tap. The secondary coil may comprise a second center tap. At least one of the primary coil and the secondary coil may be a multi-turn coil.

In some embodiments, the semiconductor device further comprises a reference plane disposed on a third layer of metal. The reference plane surrounds the primary coil and the secondary coil is coupled to the reference node. The reference node is configured to be coupled to ground.

In other embodiments, a first circuit is coupled to a first end and a second end of the secondary coil. A biasing circuit is coupled to the second center tap coupled to the secondary coil. The first circuit is configured to operate at a millimeter wave frequency. In various embodiments, the semiconductor device further comprises a millimeter wave signal source coupled to the first and second contact terminals. An inductance of the primary coil and a capacitance of the first and second contact terminals form a parallel resonance at a frequency within a passband of the first circuit.

Further, embodiments of the present invention include a semiconductor package comprising a primary coil of a coupler, a secondary coil of the coupler, and a center tap. The secondary coil is disposed within a semiconductor chip and the primary coil is disposed within an insulating material outside the semiconductor chip. The first and the secondary coils form the coupler and the primary coil comprises a center tap connection coupled to a reference node. The reference node may comprise a ground node.

In various embodiments, the primary coil is disposed in a redistribution layer disposed on the semiconductor chip. A circuit disposed within the semiconductor chip coupled to the secondary coil, wherein the circuit is configured to operate at millimeter wave frequencies. The secondary coil may also include a second center tap connection coupled to a bias circuit of the circuit disposed within the semiconductor chip.

A method of forming a semiconductor package is also presented. A semiconductor substrate is provided. A secondary coil is formed in a first metal layer over the semiconductor substrate and a first dielectric layer is formed over the secondary coil. A primary coil is formed in a second metal layer over the first dielectric layer and the secondary coil. A connection is formed between a first center tap of the primary coil and a reference node. Contact terminals are formed and coupled to the primary coil.

In some embodiments, a reference plane is formed in a third metal layer bordering the primary coil and the secondary coil. The reference plane is coupled to the first center tap. The reference plane may also be coupled to a ground node. In still other embodiments, a circuit may be formed in the semiconductor substrate and the interface of the circuit may be coupled to the secondary coil. Further, a biasing circuit may be formed in the semiconductor substrate and the biasing circuit may be coupled to a second center tap of the secondary coil. The semiconductor package is then encapsulated.

Additionally, a method of operating a semiconductor device is also provided. The semiconductor device comprises a semiconductor substrate, a primary coil of a coupler disposed over the semiconductor substrate, and a secondary coil of the coupler disposed over the semiconductor substrate adjacent to the primary coil. The primary coil comprises a first end coupled to a first contact terminal, a second end coupled to a second contact terminal, and a first center tap coupled to a reference node. The reference node may comprise a ground node.

A millimeter wave signal is applied to the first and second contact terminals. The application of the millimeter wave signal may occur at a first frequency. The millimeter wave signal is received from the primary coil via the secondary coil, wherein the receiving is performed by a circuit disposed on the semiconductor substrate that is coupled to the secondary coil.

In various embodiments, a bias voltage is applied to a second center tap of the secondary coil. An ESD pulse is received at the first and second contact terminals. The ESD pulse is shunted to an ESD signal path coupled to the reference node via the first center tap. The signal path comprises a metal region surrounding the coupler.

In other embodiments, a millimeter wave signal is transmitted to a load coupled to the first and second contact terminals from a circuit coupled to the secondary coil. A capacitance of the first and second contact terminals may be resonated with an inductance of the primary coil.

Advantages of the embodiment devices include the ability to provide ESD protection at varying high frequencies. Further, various embodiments have a low inductance to ground. Thus, embodiments of the present invention provide circuit protection against ESD pulses while maintaining desired signal performance at a variety of frequencies. In particular, with the use of an illustrative embodiment, the semiconductor package may be formed such that ESD protection circuits are unnecessary and therefore, the parasitic capacitance of ESD protection circuits may be eliminated. The embodiments described herein provide adequate signal performance with millimeter wave applications, maintain small size and compact packaging options, as well as extend the life of the semiconductor chip and its components.

While this invention has been described with reference to illustrative embodiments, this description is not intended to be construed in a limiting sense. Various modifications and combinations of the illustrative embodiments, as well as other embodiments of the invention, will be apparent to persons skilled in the art upon reference to the description. As an illustration, the embodiments described in FIG. 1-12 may be combined with each other in various embodiments. It is therefore intended that the appended claims encompass any such modifications or embodiments.

Although the present invention and its advantages have been described in detail, it should be understood that various changes, substitutions and alterations can be made herein without departing from the spirit and scope of the invention as defined by the appended claims. For example, it will be readily understood by those skilled in the art that many of the features, functions, processes, and materials described herein may be varied while remaining within the scope of the present invention.

Moreover, the scope of the present application is not intended to be limited to the particular embodiments of the process, machine, manufacture, composition of matter, means, methods and steps described in the specification. As one of ordinary skill in the art will readily appreciate from the disclosure of the present invention, processes, machines, manufacture, compositions of matter, means, methods, or steps, presently existing or later to be developed, that perform substantially the same function or achieve substantially the same result as the corresponding embodiments described herein may be utilized according to the present invention. Accordingly, the appended claims are intended to include within their scope such processes, machines, manufacture, compositions of matter, means, methods, or steps.

What is claimed is:

1. A semiconductor device comprising:
a semiconductor substrate;
a primary coil of a coupler disposed over the semiconductor substrate, wherein the primary coil comprises a first end coupled to a first contact terminal, a second end coupled to a second contact terminal, and a first center tap coupled to a reference node; and
a secondary coil of the coupler disposed over the semiconductor substrate adjacent to the primary coil.

2. The semiconductor device of claim 1, wherein the primary coil is disposed above the secondary coil.

3. The semiconductor device of claim 1, wherein the first and second contact terminals are configured to be couple to signal path coupled to the reference node via the first center tap.

4. The semiconductor device of claim 1, wherein the primary coil is disposed on a first layer of metal and the secondary coil is disposed on a second layer of metal.

5. The semiconductor device of claim 4, further comprising a reference plane disposed on a third layer of metal, wherein:
the reference plane surrounds the primary coil and the secondary coil; and
the reference plane is coupled to the reference node.

6. The semiconductor device of claim 5, wherein the reference node is configured to be coupled to ground.

7. The semiconductor device of claim 1, further comprising a circuit coupled to a first end and a second end of the secondary coil.

8. The semiconductor device of claim 1, wherein the secondary coil comprises a second center tap.

9. The semiconductor device of claim 8, further comprising
a first circuit coupled to a first end and a second end of the secondary coil; and
a biasing circuit is coupled to the second center tap coupled to the secondary coil.

10. The semiconductor device of claim 9, wherein the first circuit is configured to operate at a millimeter wave frequency.

11. The semiconductor device of claim 10, further comprising a millimeter wave signal source coupled to the first and second contact terminals.

12. The semiconductor device of claim 10, wherein an inductance of the primary coil and a capacitance of the first and second contact terminals form a parallel resonance at a frequency within a passband of the first circuit.

13. The semiconductor device of claim 1, wherein at least one of the primary coil and the secondary coil is a multi-turn coil.

14. The semiconductor device of claim 1, wherein the primary coil is magnetically coupled to the secondary coil.

15. The semiconductor device of claim 1, wherein the coupler comprises a transformer.

16. A semiconductor package comprising:
a secondary coil of a coupler disposed within a semiconductor chip; and
a primary coil of the coupler disposed within an insulating material outside the semiconductor chip, wherein the primary coil comprises a first center tap connection coupled to a reference node.

17. The semiconductor package of claim 16, wherein the reference node comprises a ground node.

18. The semiconductor package of claim 16, wherein the primary coil is disposed in a redistribution layer that is disposed over the semiconductor chip.

19. The semiconductor package of claim 16, further comprising a circuit disposed within the semiconductor chip coupled to the secondary coil, wherein the circuit is configured to operate at millimeter wave frequencies.

20. The semiconductor circuit of claim 19, wherein the secondary coil comprises a second center tap connection coupled to a bias circuit of the circuit disposed within the semiconductor chip.

21. A method of forming a semiconductor package, the method comprising:
providing a semiconductor substrate;
forming a secondary coil in a first metal layer over the semiconductor substrate;
forming a first dielectric layer over the secondary coil;
forming a primary coil in a second metal layer over the first dielectric layer and the secondary coil;
forming a connection between a first center tap of the primary coil and a reference node; and
forming contact terminals coupled to the primary coil.

22. The method of claim 21, further comprising:
forming a reference plane in a third metal layer bordering the primary coil and the secondary coil; and
coupling the reference plane to the first center tap.

23. The method of claim 22, further comprising coupling the reference plane to a ground node.

24. The method of claim 21, further comprising
forming a circuit in the semiconductor substrate; and
coupling an interface of the circuit to the secondary coil.

25. The method of claim 24, further comprising:
forming a biasing circuit in the semiconductor substrate; and
coupling the biasing circuit to a second center tap of the secondary coil.

26. The method of claim 21, further comprising encapsulating the semiconductor package.

27. A method of operating a semiconductor device comprising a semiconductor substrate, a primary coil of a coupler disposed over the semiconductor substrate, and a secondary coil of the coupler disposed over the semiconductor substrate adjacent to the primary coil, wherein the primary coil comprises a first end coupled to a first contact terminal, a second end coupled to a second contact terminal, and a first center tap coupled to a reference node, wherein the method comprises:
applying a millimeter wave signal to the first and second contact terminals; and
receiving the millimeter wave signal from the primary coil via the secondary coil, wherein the receiving is performed by a circuit disposed on the semiconductor substrate that is coupled to the secondary coil.

28. The method of claim 27, further comprising applying a bias voltage to a second center tap of the secondary coil.

29. The method of claim 27, further comprising:
receiving an electrostatic discharge (ESD) pulse at the first and second contact terminals; and
shunting the ESD pulse to an ESD signal path coupled to the reference node via the first center tap.

30. The method of claim 29, wherein the reference node comprises a ground node.

31. The method of claim 29, wherein the ESD signal path comprises a metal region surrounding the coupler.

32. The method of claim 27, further comprising transmitting a millimeter wave signal to a load coupled to the first and second contact terminals from a circuit coupled to the secondary coil.

33. The method of claim 27, wherein:
applying the millimeter wave signal comprises applying the millimeter wave signal at a first frequency; and
the method further comprises resonating a capacitance of the first and second contact terminals with an inductance of the primary coil.
